(19) United States
(12) Patent Application Publication
(10) Pub. No.: US 2001/0013651 A1
(43) Pub. Date: Aug. 16, 2001

(54) Semiconductor device and manufacturing method therefor

(76) Inventor: Fumiki Nakazawa, Chino-shi (JP)

Correspondence Address: HOGAN & HARTSON L.L.P., 500 S. GRAND AVENUE, SUITE 1900, LOS ANGELES, CA, 90071-2611, US

(21) Appl. No.: 09/738,554

(22) Filed: Dec. 15, 2000

(30) Foreign Application Priority Data
Dec. 24, 1999 (JP) 11-367013
Dec. 5, 2000 (JP) 2000-369972

(51) Int. Cl. H01L 23/48; H01L 23/52; H01L 29/40

(52) U.S. Cl. 257/737

(57) ABSTRACT

A semiconductor device featuring high yield and high reliability is provided. The semiconductor device includes a pad member having an electrical connection region, a passivation layer formed around the electrical connection region, and a bump electrode formed on the pad member. The bump electrode includes an electroless metal plating layer formed on the electrical connection region, and an electroless gold plating layer covering the electroless metal plating layer. The electroless gold plating layer has a thickness of 0.4 μm or more.

### BACKGROUND OF THE INVENTION

1. Field of the Invention

The present invention relates to a semiconductor device and a manufacturing method for the same and, more particularly to, a semiconductor device featuring a high yield and high reliability and a manufacturing method for the same.

2. Description of the Related Art

With the increasing trend toward higher integration of semiconductor integrated circuits (ICs) and smaller semiconductor chips, there has been a strong demand for a mounting technology that permits terminals to be connected at extremely small pitches. Tape automated bonding (TAB) used for tape carrier packages may be a mounting technology that meets such a demand.

In the TAB mounting, a lead terminal is connected to a bump electrode. Bump electrodes are typically represented by gold bump electrodes, which are generally formed by electroplating. An example will be described below in which a gold bump electrode is formed by the electroplating on an electrical connection region of a pad member composed of aluminum.

The pad member is electrically connected to internal semiconductor elements, and an area around the pad member is covered with a passivation layer.

A barrier metal layer and a protective metal layer known as “under-bump metal layers” are formed by sputtering. Thereafter, a resist for forming a bump that exposes the electrical connection region and the area around the electrical connection region of the pad member is formed by photolithography. Then, a gold layer is deposited by the electroplating according to a pattern of the resist. Next, the resist is removed, and the under-bump metal layer composed of a few different layers is subjected to wet etching by using the gold layer formed by the electroplating as a mask. As necessary, annealing or the like may be carried out to complete the gold bump. A cleaning step may be added before and after each step.

The process for forming a bump by using the electroplating according to the above procedure involves many steps. There has been demand for further reducing the number of steps of the process. To meet the demand, there has recently been proposed a method for forming a bump electrode by electroless plating.

A bump forming method by the electroless plating has been disclosed in, for example, U.S. Pat. No. 4,205,099. The publication discloses a bump forming method based on nickel electroless plating. The process for forming a bump by employing the electroless plating allows omission of mainly a sputtering step and an etching step for forming an under-bump metal layer that are required for forming a bump by the electroplating, and a step for producing a resist for plating deposition. In other words, the method for forming bump electrodes by the electroless plating permits a markedly shortened process, and accordingly allows bump electrodes to be formed more quickly at lower cost, thus attracting attention in the industry.

### SUMMARY OF THE INVENTION

Accordingly, it is an object of the present invention to provide a semiconductor device that can be obtained by electroless plating and features higher yield and higher reliability.

It is another object of the present invention to provide a manufacturing method for a semiconductor device that permits a reduced number of processing steps and reduced production cost.

According to one aspect of the present invention, there is provided a semiconductor device including a pad member that is formed on a base and has an electrical connection region, an insulating layer formed in an area around the electrical connection region, and a bump electrode formed on the pad member, wherein the bump electrode includes an electroless metal plating layer and an electroless gold plating layer covering the electroless metal plating layer, and the electroless gold plating layer has a thickness of 0.4 μm or more.

In the present invention, the electrical connection region is a region in the pad member that is not covered by the insulating layers and is joined to the bump electrode when the bump electrode is formed on the pad member. The base includes at least a substrate with a semiconductor element formed thereon and a wiring layer formed thereon.

In the semiconductor device according to the present invention, the electroless gold plating layer has a thickness of 0.4 μm or more; hence, when the semiconductor device is joined to a lead wire included in, for example, a tape carrier package, or a joining member, such as a terminal electrode, included in a flexible printed board, a sufficiently high bond strength can be secured, permitting good junction to be accomplished.

According to another aspect of the present invention, there is provided a semiconductor device including a pad member that is formed on a base and has an electrical connection region, an insulating layer formed in an area around the electrical connection region, a bump electrode formed on the pad member, and a mounting member including a joining member, wherein the bump electrode includes an electroless metal plating layer and an electroless gold plating layer covering the electroless metal plating layer, the joining member constituting the mounting member is joined to the bump, and the electroless gold plating layer has a thickness of 0.4 μm or more.

In the semiconductor device according to the present invention, the electroless gold plating layer has a thickness of 0.4 μm or more; hence, a sufficiently high bond strength can be obtained at the junction of the bump electrode and the joining member, enabling the semiconductor device to survive a temperature cycling test and an long-term reliability test. Thus, the semiconductor device in accordance with the present invention is highly reliable and ensures higher yield.

Preferably, the joining member has at least a surface thereof covered by a layer composed of tin or gold.

Preferably, the mounting member is a taping member, and the joining member is a lead wire included in the taping member.

Preferably, the mounting member is a flexible printed board, and the joining member is a terminal electrode included in the flexible printed board.

Preferably, a side fillet is continuously formed at the junction of the electroless gold plating layer and the joining member.

Preferably, the side fillet is formed of a gold-tin eutectic or a gold-gold eutectic.

According to yet another aspect of the present invention, there is provided a first manufacturing method for a semiconductor device, including the steps of forming a pad member in a predetermined region on a substrate, forming an insulating layer to cover the pad member, exposing an electrical connection region in the pad member, leaving the insulating layer in an area around the pad member, by photolithography, forming an electroless metal plating layer on the pad member by electroless plating, and forming a bump electrode on the electrical connection region by forming an electroless gold plating layer covering the electroless metal plating layer by electroless gold plating, the electroless gold plating layer being formed to have a thickness of 0.4 μm or more.

The manufacturing method for a semiconductor device in accordance with the present invention makes it possible to omit mainly a sputtering step for forming an under-bump metal layer, etching, and a step for forming a resist for plating deposition, which are required in the process employing the electroplating in the conventional bump electrode forming process based on the electroplating. Hence, a markedly shortened process can be expected, and a reduction in production cost can be achieved.

According to a further aspect of the present invention, there is provided a second manufacturing method for a semiconductor device, including the steps of forming a pad member in a predetermined region on a substrate, forming an insulating layer to cover the pad member, exposing an electrical connection region in the pad member, leaving the insulating layer in an area around the pad member, by photolithography, forming an electroless metal plating layer on the pad member by electroless plating, forming a bump on the electrical connection region by forming an electroless gold plating layer covering the electroless metal plating layer by electroless gold plating, the electroless gold plating layer being formed to have a thickness of 0.4 μm or more, and joining a joining member included in a mounting member to the bump electrode.

The second manufacturing method for a semiconductor device provides the same advantages as those of the first manufacturing method for a semiconductor device.

Preferably, the joining member has at least a surface thereof covered by a layer composed of tin or gold.

Preferably, the mounting member is a taping member, and the joining member is a lead wire included in the taping member.

Preferably, the mounting member is a flexible printed board, and the joining member is a terminal electrode included in the flexible printed board.

Preferably, a side fillet is continuously formed at the junction of the electroless gold plating layer and the joining member in a step for joining the joining member and the bump electrode.

Preferably, the side fillet is formed of a gold-tin eutectic or a gold-gold eutectic.

### BRIEF DESCRIPTION OF THE DRAWINGS

FIG. 1 is a sectional view showing a semiconductor device according to an embodiment of the present invention;

FIG. 2 is a top plan overview illustrating a bump electrode shown in FIG. 1 to which an inner lead wire has been connected;

FIG. 3 is a sectional view taken along the line F3-F3 of FIG. 2;

FIG. 4 is a table showing evaluation results of TAB-mounted bump electrodes on an IC chip including the bump electrode shown in FIG. 1;

FIG. 5 is a sectional view showing a semiconductor device obtained by joining the IC chip including the bump electrode shown in FIG. 1 and a taping member;

FIG. 6 is a sectional view showing a semiconductor device obtained by joining the IC chip including the bump electrode shown in FIG. 1 and a flexible printed board; and

FIG. 7 is a top plan overview showing an undesirable example of connection of an inner lead wire to a bump electrode.

### DESCRIPTION OF THE PREFERRED EMBODIMENTS

FIG. 1 is a sectional view showing a semiconductor device 100 according to an embodiment of the present invention. In the semiconductor device 100, an insulating layer 10 is formed on a semiconductor substrate (not shown), and a pad member 11 is formed on the insulating layer 10. This embodiment illustrates a case where the pad member 11 is composed primarily of aluminum. The pad member 11 is electrically connected to an internal semiconductor element (not shown). A passivation layer 12 is formed, as an insulating layer, on the insulating layer 10 and an area around the pad member 11. There is no restrictions, in particular, to the type of the passivation layer 12. A SiO₂ layer, a SiN layer, a phosphosilicate glass (PSG) layer, or other type of layer may be used for the passivation layer 12 as long as it eases an impact while a bump electrode is being mounted and contributes to prevention of the occurrence of cracks. For instance, if the SiO₂ layer is used for the passivation layer 12, then the thickness layer 12 will be about 2 μm. The passivation layer 12 may alternatively be formed of multiple layers. The passivation layer 12 composed of multiple layers may include, for example, the SiO₂ layer and a SiN layer.

A bump electrode 20 is formed on the pad member 11, the bump electrode 20 being joined to the pad member 11 in an electrical connection region 15. The bump 20 is constituted by an electroless metal plating layer 13 and an electroless gold plating layer 14 covering the surface of the electroless metal plating layer 13. The electroless metal plating layer 13 is formed of a nickel layer formed by electroless plating, and the nickel layer constituting the electroless metal plating layer 13 is formed by self-precipitation of nickel onto the pad member 11.

The electroless metal plating layer 13, which virtually decides the size of a bump electrode, has a height or thickness of about 20 μm, which can be changed according to the size of a bump electrode.

The bump electrode 20 has an electroless gold plating layer 14 covering the electroless metal plating layer 13. The electroless gold plating layer 14 has a thickness T of 0.4 μm or more (see FIG. 1). The electroless gold plating layer 14 is the uppermost layer of the layers making up the bump electrode 20, and if the thickness thereof is 0.4 μm or more, then a gold layer in a quantity that is sufficient for accomplishing reliable junction to a joining member, such as a lead wire representative of TAB mounting will be formed, making it possible to secure adequate strength of junction to the joining member.

A manufacturing method for the semiconductor device 100 shown in FIG. 1 will now be described. First, the insulating layer 10 is formed on a semiconductor substrate (not shown) incorporating an integrated circuit composed of semiconductor elements, then the pad member 11 formed primarily of aluminum is formed on the insulating layer 10. Thereafter, the passivation layer 12 composed of the SiO₂ layer in formed, by chemical vapor deposition (CVD), to a thickness of about 2 μm such that it covers the pad member 11. In this step, the passivation layer 12 may be have a laminated structure in which the SiO₂ layer is combined with a different type of layer, such as a SiN layer, as mentioned above. Subsequently, the electrical connection region 15 for connecting the pad member 11 and the bump electrode 20 is exposed, by lithography, at the center of the top surface of the pad member 11, leaving the passivation layer 12 in the peripheral edge area of the top surface of the pad member 11.

In the following step, a pretreatment for forming the electroless metal plating layer 13 composed of nickel is performed on the region of the top surface of the pad member 11 where the electroless metal plating layer 13 is to be formed. The pretreatment is zincate treatment for substituting aluminum on the surface of the pad member 11 by zinc in a treatment solution. More specifically, in the zincate treatment, the workpiece is immersed in a treatment solution containing zinc ions to substitute aluminum by zinc by the reaction represented by 2Al+3Zn²⁺→2Al³⁺+3Zn.

In the next step, the workpiece is immersed in a plating solution composed primarily of nickel ions, a reducing agent typically represented by sodium hypophosphite, a stabilizing agent, and a buffer so an to cause nickel to self-precipitate. Thus, the nickel layer obtained by the electroless plating constitutes 90% or more of a predetermined bump height. Then, the workpiece is immersed in a plating solution composed primarily of gold ions, a reducing agent, a stabilizing agent, and a buffer to provide electroless gold plating. In this step, the plating time is controlled so that the self-precipitation of gold amounts to 0.4 μm or more. Thereafter, the workpiece is subjected to a cleaning step to complete the bump electrode 20 formed of the electroless metal plating layer 13 and the electroless gold plating layer 14, as shown in FIG. 1.

The precipitating rate of the gold plating for forming the electroless gold plating layer 14 is extremely slow; it is one hundredth or less of the precipitating rate of the nickel plating in the electroless nickel plating step, which is the preceding step. Hence, increasing the thickness of the gold plating layer requires a considerable time. For this reason, although the thickness of the electroless gold plating layer 14 must be 0.4 μm or more, the thickness does not have to be great as long as it allows a side fillet to be continuously formed at the junction by the gold-tin eutectic to at least an object to be connected, and allows sufficient bond strength to be secured between the bump electrode and the object to be connected.

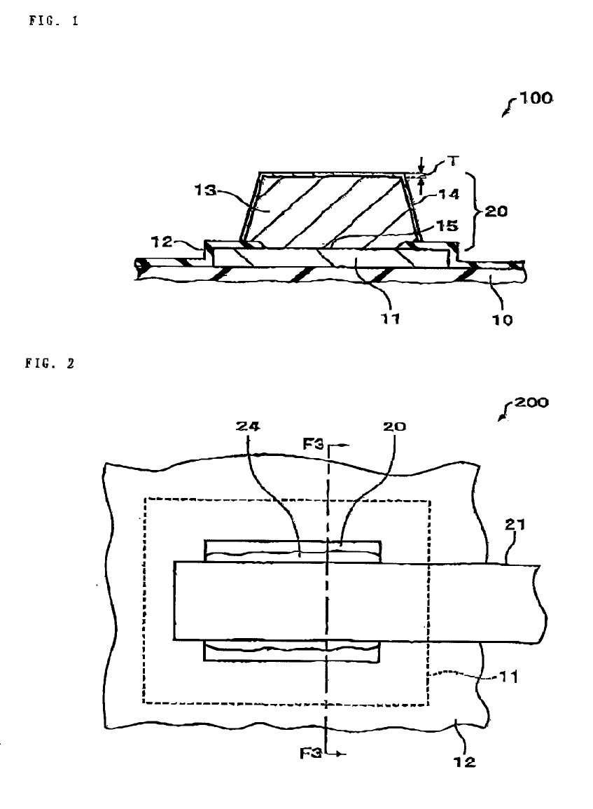

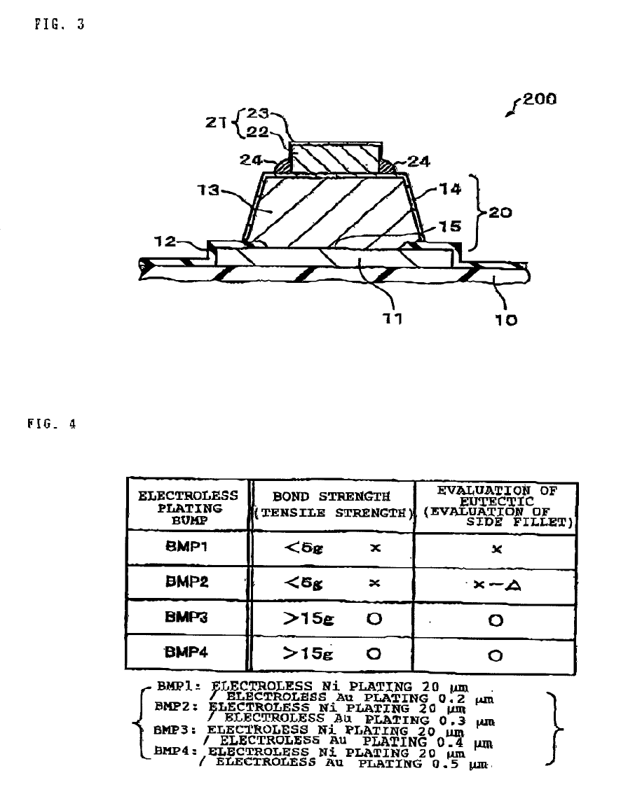

FIG. 2 and FIG. 3 are overviews showing an inner lead wire connection, such as TAB, implemented on the bump electrode 20 shown in FIG. 1, wherein FIG. 2 is a top plan view, and FIG. 3 is a sectional view taken along the line F3-F3 of FIG. 2. A lead wire 21, which is a joining member for joining to the bump electrode 20, is constituted by a copper layer 22 and a tin plating layer 23 that is about 0.2 μm thick and covers the entire copper layer 22. In this connection state, as shown in FIG. 2, an eutectic at the junction based on the gold-tin eutectic is continuously formed as a side fillet 24 along the junction. In other words, forming the electroless gold plating layer 14 to have the thickness of 0.4 μm or more provides good junction between the bump electrode 20 and the lead wire 21.

FIG. 4 shows the results of evaluation of the bump electrodes 20, each of which is composed of the electroless metal plating layer 13 and the electroless gold plating layer 14, as shown in FIG. 1. These bump electrodes have been applied to IC chips and TAB-mounting. Each of the IC chips is about 10.8×2.8 mm large, and has a pad pitch of about 70 μm and an aluminum opening (electrical connection region) of about 26×64 μm. Using the pad members having such a configuration, the semiconductor devices having the electroless gold plating layers 14 of different thicknesses in the bump electrode 20 shown in FIG. 1 were formed, the bump electrodes being indicated by BMP 1 through BMP 4. In the bump electrodes BMP 1 through 4, the electroless metal plating layers 13 share the same thickness of 20 μm, while the electroless gold plating layers 14 have different thickness, namely, about 0.2 μm, about 0.3 μm, about 0.4 μm, and about 0.5 μm, respectively.

The inner lead 21 to be connected to the bump electrodes BMP 1 through BMP 4 is constructed so that a tin plating layer 23 covers the entire copper layer 22, as shown in FIG. 2 and FIG. 3. For example, the inner lead 21 includes the copper layer 22 having a width of about 30 μm that is entirely covered by the tin plating layer 23 having a thickness of about 0.2 μm. After joining the inner lead 21 to each of the bump electrodes BMP 1 through BMP 4, measurement on their bond strength or tensile strength was carried out. In the measurement performed on each of the bump electrodes, the force for pulling the inner lead 21 was gradually increased, and the values of strength at which the inner leads 21 came off the bump was shown as the bond strength in FIG. 4. Using a pull tester as the measuring instrument, a hook-shaped measuring probe was hooked onto the inner lead 21, which is the joining member, and the inner lead 21 was pulled in virtually perpendicular direction at a rate ranging from 40 to 60 mm/s.

Referring to FIG. 4, a bond strength exceeding 15 grams is denoted by “O”, while a bond strength below 5 grams is denoted by “X”.

At the same time, the eutectics formed at the junctions of the inner leads 21 and the bump electrodes were also evaluated. More specifically, the configurations or the like of side fillets were also evaluated. Regarding the evaluation results of the eutectics shown in FIG. 4, a state wherein a side fillet has been continuously formed is denoted by “O”, a state wherein the side fillet has been discontinuously formed in an area amounting to below 50% of the junction is denoted by “Δ”, and a state wherein the side fillet has been discontinuously formed in an area amounting to 50% or more of the junction is denoted by “X”.

The same mounting conditions have been applied to all the bump electrodes BMP 1 through BMP 4. To be more specific, the heating temperature of a press-bonding tool was set to about 500° C., the temperature for heating the lower part of a stage that opposes the press-bonding tool was set to about 100° C., and a load of about 50 grams was applied to each bump, thereby accomplishing thermal press-bonding.

Referring back to FIG. 4, if the bond strength of a bump is below 5 grams, then the semiconductor device will not survive the long-term reliability test and the temperature cycling test that are performed following a mounting step. More specifically, after the joining member and the bump electrode are joined, the semiconductor device is sealed with a resin, and when the semiconductor device is subjected to heat during the long-term reliability test and the temperature cycling test that are carried out later, the junction between the inner lead, which serves as the joining member, and the bump develops distortion due to a difference in thermal expansion rate between the chip and the resin. In this case, if the bond strength of the joining member and the bump is below 5-gram level, then the distortion developed between the junction and the bump electrode is very likely to cause the bump electrode to be cracked or come off.

If the bond strength exceeds 15-gram level, then the semiconductor device will he able to survive the distortion taking place in the junction between the joining member and the bump electrode in the long-term reliability test and the temperature cycling test carried out after the mounting step.

The long-term reliability in this embodiment refers to a test for evaluating the durability of a device by subjecting the device to an atmosphere of high temperature and high humidity for a predetermined time in order to evaluate the long-term reliability of the device. In the long-term reliability test in the present invention, the devices were placed in an atmosphere of a relative humidity of 85% and a temperature of 85° C. for 1000 hours.

The temperature cycling test refers to a test conducted to evaluate the durability of a device against temperature changes. The temperature cycling test in the present invention consists of 200 repeated cycles, each cycle including temperature changes made over 30 minutes within the range of −65° C. to 150° C.

Referring to FIG. 4 the bump electrode BMP 1 having the 0.2 μm-thick electroless gold plating layer and the bump electrode BMP 2 having the 0.3 μm-thick electroless gold plating layer come off at a tensile strength level of 5 grams or less. As indicated in FIG. 4, these bump electrodes BMP 1 and BMP 2 show poor evaluation results on the side fillets thereof. This means that the side fillets of the bump electrodes BMP1 and BMP2 are discontinuously formed.

FIG. 7 is a top plan view showing the overview of the bump electrodes BMP1 or BMP 2 to which the inner lead has been connected. In the connection illustrated in FIG. 7, a side fillet 124 formed at the junction by the gold-tin eutectic is discontinuous, presenting defective junction. The result is poor bond strength below 5 grams, making it impossible to obtain high reliability.

In contrast to the above, the bump electrode BMP 3 having the 0.4 μm-thick electroless gold plating layer and the bump electrode BMP 4 having the 0.5 μm-thick electroless gold plating layer do not come off even at a tensile strength level exceeding 15 grams, as shown in FIG. 4. These bump electrodes naturally show good evaluation results on their side fillets. More specifically, as illustrated in FIG. 2, the side fillet 24 formed at the junction between the inner lead 21 and the bump electrode 20 has been continuously formed. The evaluation results described above indicate that an appropriate thickness of the electroless gold plating layer constituting the bump electrode ranges from 0.4 μm to about 0.5 μm, considering the time required for plating.

The embodiment has shown a case where the inner lead 21 includes the copper layer having a width of about 30 μm is covered by the tin plating layer having a thickness of about 0.2 μm. The same results, however, have been obtained also with an inner lead that includes a copper layer covered by a tin plating layer having a thickness ranging from 0.2 μm to 0.6 μm. Furthermore, the same results have been obtained also when a gold plating layer was used to replace the tin plating layer.

FIG. 5 is a sectional view of a semiconductor device 300 fabricated by joining an IC chip 51, which includes the bump electrode 20 shown in FIG. 1, and a taping member (to be discussed hereinafter). In the semiconductor device 300, an inner lead 53 serving as a joining member is formed on a taping member (a TAB tape 52 in FIG. 5) serving as a mounting member, and the inner lead 53 and the electrode bump 20 are joined. In other words, the semiconductor device 300 is an example of a mounting product fabricated by the TAB tape.

The semiconductor device 300 includes the IC chip 51 on which the bump electrodes 20 shown in FIG. 1 have been formed, and the TAB tapes 52 joined to the bump electrodes 20 through the inner leads 53. In the semiconductor device 300 shown in FIG. 5, the areas around the bump electrodes 20 have the same structure as that in the semiconductor device 200 described above. More specifically, an insulating layer (not shown) is formed on a semiconductor substrate (not shown) in the IC chip 51, a pad member (not shown) is formed on the insulating layer, a passivation layer (not shown) is formed, as an insulating layer, on the above insulating layer and the area around the pad member, and the bump electrode 20 is formed on the pad member.

In the semiconductor device 300, the thickness of the electroless gold plating layer 14 constituting the bump 20 is 0.4 μm or more, and the side fillet (not shown) is continuously formed at the junction, which is composed of the gold-tin eutectic, to the inner lead 53, as in the case of the semiconductor device 200 shown in FIG. 2. Hence, sufficiently high bond strength can be secured in the junction between the bump electrodes 20 and the inner leads 53.

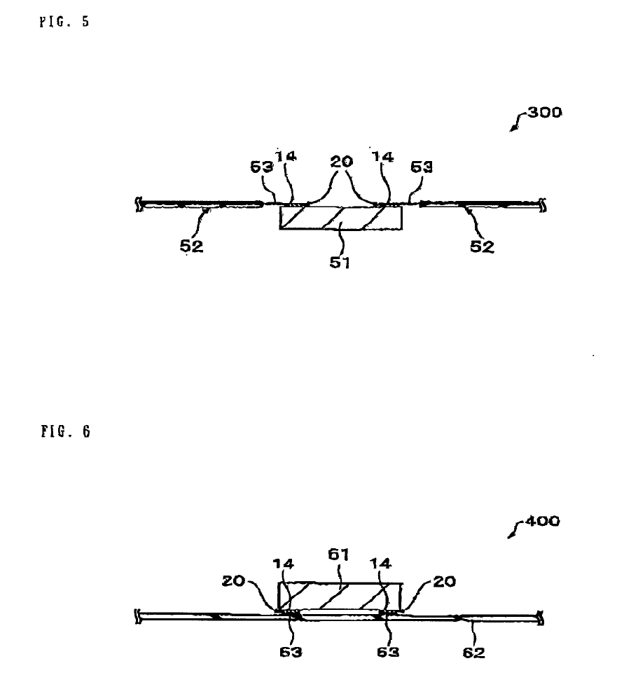

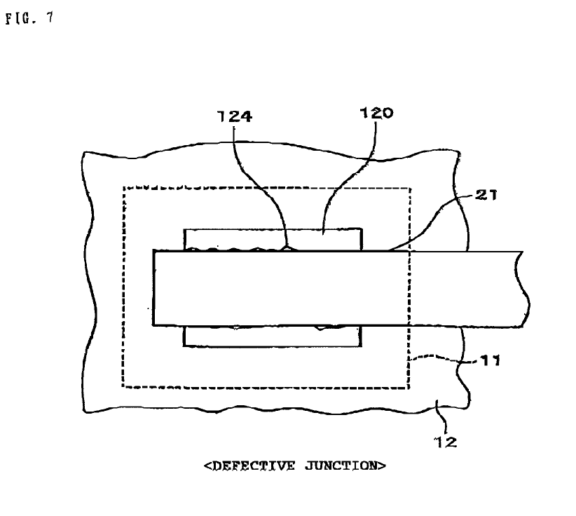

FIG. 6 is a sectional view of a semiconductor device 400 fabricated by joining an IC chip 61 including the bump electrodes 20 shown in FIG. 1 and a flexible printed board (which will be discussed hereinafter). In the semiconductor device 400, terminal electrodes 63 are formed, as joining members, on the flexible printed board (a flexible printed board 62 in FIG. 6), which is a mounting member, and the terminal electrodes 63 and the bump electrodes 20 are connected. The semiconductor device 400 is an example of a mount product of a chip-on-film (COF) or flexible semiconductor device.

The semiconductor device 400 includes the IC chip 61, on which the bump electrodes 20 shown in FIG. 1 are formed, and the flexible printed board 62 joined to the bump electrodes 20 through the terminal electrodes 63. In the semiconductor device 400 also, the thickness of the electroless gold plating layer 14 constituting the bump 20 is 0.4 μm or more, and the side fillet (not shown) is continuously formed at the junction, which is composed of the gold-tin eutectic, to the terminal electrodes 63, as in the case of the semiconductor devices 200 and 300 shown in FIG. 2 and FIG. 5, respectively. Hence, sufficiently high bond strength can be secured in the junction between the bump electrodes 20 and the terminal electrodes 63.

Thus, according to the semiconductor devices of the embodiments, the thickness of the electroless gold plating layer constituting the outermost layer of a bump is set to 0.4 μm or more so as to continuously form a side fillet composed of a gold-tin eutectic along a junction between the bump and a joining member. This arrangement allows sufficiently high bond strength to be secured at the junction between a bump and a joining member, thus enabling a semiconductor device to survive a temperature cycling test and a long-term reliability test. Hence, the semiconductor devices according to the embodiments feature high reliability and high yield.

Moreover, the bump electrodes formed by the electroless plating can be suitably used for inner lead connection typically represented by TAB and eutectic connection applied to COF or the like.

Furthermore, the manufacturing method for the semiconductor devices in accordance with the embodiments permits the omission of mainly a sputtering step for forming an under-bump metal layer, etching, and a step for forming a resist for plating growth, which are required in the conventional bump forming process employing the electroplating. Hence, a markedly shortened process can be expected, and a reduction in production cost can be achieved.

In the foregoing embodiments, a copper layer may be used in place of the nickel layer for the electroless metal plating layer 13. To form the copper layer by the electroless plating, a workpiece is immersed in a plating solution composed primarily of copper ions, a reducing agent, a stabilizing agent, and a buffer to cause copper to self-precipitate, thereby forming 90% or more of a predetermined height of a bump electrode by electroless copper plating. Then, the workpiece is immersed in a plating solution composed primarily of gold ions, a reducing agent, a stabilizing agent, and a buffer to provide electroless gold plating layer that covers the electroless metal plating layer composed of the copper layer. In this case, the thickness of the electroless gold plating layer formed by the self-precipitation is set to 0.4 μm or more, as in the case of the aforesaid bump electrode 20, in order to secure adequate bond strength at the junction between a bump electrode and a joining member.

What is claimed is:

1. A semiconductor device comprising:
a pad member that is formed on a base and has an electrical connection region;
an insulating layer formed in an area around the electrical connection region; and
a bump electrode formed on the pad member,
wherein the bump electrode includes an electroless metal plating layer and an electroless gold plating layer covering the electroless metal plating layer; and
the electroless gold plating layer has a thickness of 0.4 μm or more.

2. A semiconductor device comprising:
a pad member that is formed on a base and has an electrical connection region;
an insulating layer formed in an area around the electrical connection region;
a bump electrode formed on the pad member; and
a mounting member including a joining member,
wherein the bump electrode includes an electroless metal plating layer and an electroless gold plating layer covering the electroless metal plating layer;
the joining member constituting the mounting member is joined to the bump electrode; and
the electroless gold plating layer has a thickness of 0.4 μm or more.

3. A semiconductor device according to claim 2, wherein
the joining member has at least a surface thereof covered by a layer composed of tin or gold.

4. A semiconductor device according to claim 2 or 3, wherein
the mounting member is a taping member, and
the joining member is a lead wire included in the taping member.

5. A semiconductor device according to claim 2 or 3, wherein
the mounting member is a flexible printed board, and
the joining member is a terminal electrode included in the flexible printed board.

6. A semiconductor device according to any one of claims 2 to 5, wherein
a side fillet is continuously formed at the junction of the electroless gold plating layer and the joining member.

7. A semiconductor device according to any one of claims 2 to 6, wherein
the side fillet is formed of a gold-tin eutectic or a gold-gold eutectic.

8. A manufacturing method for a semiconductor device, comprising the steps of:
forming a pad member in a predetermined region on a substrate;
forming an insulating layer to cover the pad member;
exposing an electrical connection region in the pad member, leaving the insulating layer in an area around the pad member, by photolithography;
forming an electroless metal plating layer on the pad member by electroless plating; and
forming a bump electrode on the electrical connection region by forming an electroless gold plating layer covering the electroless metal plating layer by electroless gold plating, the electroless gold plating layer being formed to have a thickness of 0.4 μm or more.

9. A manufacturing method for a semiconductor device, comprising the steps of:
forming a pad member in a predetermined region on a substrate;
forming an insulating layer to cover the pad member;
exposing an electrical connection region in the pad member, leaving the insulating layer in an area around the pad member, by photolithography;
forming an electroless metal plating layer on the pad member by electroless plating;
forming a bump electrode on the electrical connection region by forming an electroless gold plating layer covering the electroless metal plating layer by electroless gold plating, the electroless gold plating layer being formed to have a thickness of 0.4 μm or more; and
joining a joining member included in a mounting member to the bump electrode.

10. A manufacturing method for a semiconductor device according to claim 9, wherein
the joining member has at least a surface thereof covered by a layer composed of tin or gold.

11. A manufacturing method for a semiconductor device according to claim 9 or 10, wherein
the mounting member is a taping member, and
the joining member is a lead wire included in the taping member.

12. A manufacturing method for a semiconductor device according to claim 9 or 10, wherein
the mounting member is a flexible printed board, and
the joining member is a terminal electrode included in the flexible printed board.

13. A manufacturing method for a semiconductor device according to any one of claims 9 to 12, wherein
a side fillet is continuously formed at the junction of the electroless gold plating layer and the joining member in a step for joining the joining member and the bump electrode.

14. A manufacturing method for a semiconductor device according to claim 13, wherein
the side fillet is formed of a gold-tin eutectic or a gold-gold eutectic.
